(19) United States
(12) Patent Application Publication
(10) Pub. No.: US 2006/0032585 A1
(43) Pub. Date: Feb. 16, 2006

(54) Plasma processing method and apparatus

(76) Inventors: Yoshitaka Kai, Kudamatsu-shi (JP); Ken Yoshioka, Hikari-shi (JP); Tadamitsu Kanekiyo, Kudamatsu-shi (JP); Takeshi Shimada, Hikari-shi (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/198,182

(22) Filed: Aug. 8, 2005

Related U.S. Application Data
(62) Division of application No. 10/650,841, filed on Aug. 29, 2003.

(30) Foreign Application Priority Data
Jul. 18, 2003 (JP) 2003-199372

(51) Int. Cl. C23F 1/00; H01L 21/306

(52) U.S. Cl. 156/345.48; 156/345.32

(57) ABSTRACT

A high-dielectric-constant gate insulating film 32 such as HfO₂ is etched with gas plasma using gas selected from Ar gas, He gas, Ar+He mixed gas, and mixed gases formed by mixing CH₄ with the preceding gases while maintaining a temperature of 40° C. or higher, thus ensuring high etching selective ratio between a HfO₂ film 32 and a Poly-Si layer 33, a substrate Si layer 31 and a SiO₂ mask 34, reducing the amount of loss of the substrate Si layer 31 and side etching of side walls of the Poly-Si gate portion 33 during plasma etching of HfO₂.

### FIELD OF THE INVENTION

This application is a Divisional application of prior application Ser. No. 10/650,841, filed Aug. 29, 2003, the contents of which are incorporated herein by reference in their entirety.

The present invention relates to a plasma processing method and plasma etching apparatus for etching a high-dielectric-constant gate insulating film, preferable for processing a substrate to form a CMOS gate transistor module using a high-dielectric-constant gate insulating film formed of a material selected from the group consisting of HfO₂, HfSiO₂, HfSiₓN_{y}, HfSiON, HfAlₓO_{y}, ZrO₂, La₂O₃, (Al, Hf)Oₓ and Y₂O₃.

### DESCRIPTION OF THE RELATED ART

With the recent progress in the miniaturization of CMOS transistors, it seems indispensable that a new gate insulating film replacing the conventional SiO₂/SiOₓN_{y} as transistor gate insulator be introduced at least within a few years. Currently, the possible high-dielectric-film materials are narrowed down from the point of view of relative permittivity and stability on the Si surface to materials such as HfO₂ and ZrO₂ (relative permittivity: 20-30) and silicates thereof (relative permittivity: 10-20).

Contrary to this situation, however, plasma etching of high-dielectric-constant gate insulating films still has many unknown properties, such as the etching rate/uniformity, profile controllability, status of side wall deposition and other changes in property with time. These unknown properties are technical problems to be solved for future development.

Prior art methods for processing a high-dielectric-constant gate insulating film include wet etching using a solution (HF), a combination of O₂ plasma etching and wet etching (HF solution), and dry etching using Cl₂/O₂/HBr gas, but these prior art methods had drawbacks such as the occurrence of side etching of the Poly-Si film constituting the gate transistor, CD loss, and increased amount of loss of the substrate Si layer after performing etching of the high-dielectric-constant gate insulating film (refer for example to non-patent documents 1 and 2).

[Non-Patent Document 1]

IBM Research Report/RC22642 (W0206-083) Jun. 17, 2002

[Non-Patent Document 2]

Collection of Drafts for the 50th Meeting of the Japan Society of Applied Physics, 28a-ZX-9, p 877 (2003-3), “Fabrication technology of high-k gate dielectrics by dry etching process”, T. Maeda, H. Ito, R. Mitsuhashi, A. Horiuchi, T. Kawahara, A. Muto, K. Torii, H. Kitajima

A prior art method for manufacturing a CMOS transistor utilizing a high-dielectric-constant gate insulating film will now be explained with reference to FIG. 4. For example, a CMOS transistor utilizing a high-dielectric-constant gate insulating film formed of HfO₂ is manufactured using a sample (substrate) 30 comprising a substrate Si layer (Si-Sub) 31, a high-dielectric-constant gate insulating film 32 formed of HfO₂ and having a thickness of approximately 3.5 mm on the substrate Si layer 31, a Poly-Si layer 33 having a thickness of approximately 150 nm and a SiO₂ mask 34 having a thickness of approximately 50 nm laminated on the substrate. The SiO₂ mask 34 is subjected to wet etching (process A) using C₅F₈ and other solutions until an end point is detected (EPD), then the Poly-Si layer 33 is subjected to wet etching (process B) using Cl₂/O₂/HBr solution until an end point is detected (FIG. 4(A)), and thereafter, the high-dielectric-constant gate insulating film 32 formed of HfO₂ is subjected to wet etching (process C) using acidic solutions such as HF solution, to thereby manufacture the CMOS transistor. By the wet etching process (process C) of the high-dielectric-constant gate insulating film 32, as shown in FIG. 4(B), side-etching (33S) of the Poly-Si layer 33 occurs, deteriorating the shape of the CMOS gate.

Further, upon performing etching (process C) of a high-dielectric-constant gate insulating film 32 after process A and process B, it may be possible to perform dry etching using Cl₂/O₂ plasma. According to this method, however, the etching selective ratio (gate insulating film/substrate Si layer) between the substrate Si layer 31 and the high-dielectric-constant gate insulating film 32 by the Cl₂/O₂ plasma is small, and the end point detection (EPD) during etching of the high-dielectric-constant gate insulating film is difficult. Thus, the prior art method has drawbacks in that the substrate Si layer 31 is etched greatly (32E) (substrate Si layer loss) and that the Poly-Si layer 33 is side-etched (33S) making it impossible to achieve the desired profile of the CMOS gate.

According to the above-explained prior art methods, there have not been sufficient studies performed on the actual methods for performing plasma etching that reduce the amount of loss of the substrate Si layer or the amount of side etching of the side walls of the CMOS gate module.

### SUMMARY OF THE INVENTION

Therefore, the present invention aims at providing an actual plasma processing method for etching a high-dielectric-constant gate insulating film, having an improved shape controllability and advantageous etching selective ratio of the high-dielectric-constant gate insulating film with respect to the Poly-Si layer and the substrate Si layer which constitute the gate module, to thereby reduce the amount of loss of the substrate Si layer and the amount of side etching of the side walls of the gate module during etching of the high-dielectric-constant gate insulating film, solving the problems of the prior art.

The above object is achieved by a plasma processing method for subjecting a substrate electrostatically chucked onto a substrate holder to plasma processing, said substrate used for forming a transistor module utilizing a high-dielectric-constant gate insulating film formed of a material selected from the group consisting of HfO₂, HfSiO₂, HfSiₓN_{y}, HfSiON, HfAlₓO_{y}, ZrO₂, La₂O₃, (Al, Hf)Oₓ and Y₂O₃, said method comprising performing a plasma processing using a gas selected from the group consisting of Ar gas, He gas and a mixture of Ar gas and He gas.

Furthermore, the above object is achieved by a plasma processing method for subjecting a substrate electrostatically chucked onto a substrate holder to plasma processing, said substrate used for forming a transistor module utilizing a high-dielectric-constant gate insulating film formed of a material selected from the group consisting of HfO₂, HfSiO₂, HfSiₓN_{y}, HfSiON, HfAlₓO_{y}, ZrO₂, La₂O₃, (Al, Hf)Oₓ and Y₂O₃, said method comprising performing a plasma processing using a mixed gas (Ar+CH₄/He+CH₄/Ar+He+CH₄) formed by mixing a gas containing CH radicals (CH₄) to a gas selected from the group consisting of Ar gas, He gas and a mixture of Ar gas and He gas.

Moreover, the object of the present invention is achieved by the plasma processing method according to the above, wherein a temperature of either the substrate or the electrode holding the substrate is controlled to 40° C. or higher and below the durable temperature of the electrode.

### BRIEF DESCRIPTION OF THE DRAWINGS

FIG. 1 is a vertical cross-sectional view illustrating the structure of the plasma etching apparatus used in the embodiment of the present invention;

FIG. 2 is a view showing a frame format of an electrode constituting the plasma etching apparatus of FIG. 1;

FIG. 3 is a top view showing the outline of the structure of the plasma processing apparatus comprising the plasma etching apparatus used in the embodiment of the present invention;

FIG. 4 is an explanatory view of the process for manufacturing an electrode of a CMOS transistor using the high-dielectric-constant gate insulating film to which the present invention is applied;

FIG. 5 is an explanatory view showing the effect of the plasma processing method according to the present invention; and

FIG. 6 is an explanatory view illustrating the relationship between the temperature and etching rate of the plasma processing method according to the present invention.

### DETAILED DESCRIPTION OF THE PREFERRED EMBODIMENT

The preferred embodiments of the present invention will now be explained with reference to the accompanied drawings. The present invention relates to a plasma processing apparatus for etching a substrate having multiple layers including a high-dielectric-constant gate insulating film formed on a wafer, utilizing an etching apparatus that is provided with plasma forming gas to generate gas plasma by which the high-dielectric-constant gate insulating film formed on the wafer is etched. Examples of the plasma processing apparatuses that can apply the present invention include an inductively-coupled plasma etching system, a helicon plasma etching system, a dual-frequency-excited parallel plate plasma etching system and a microwave plasma etching system.

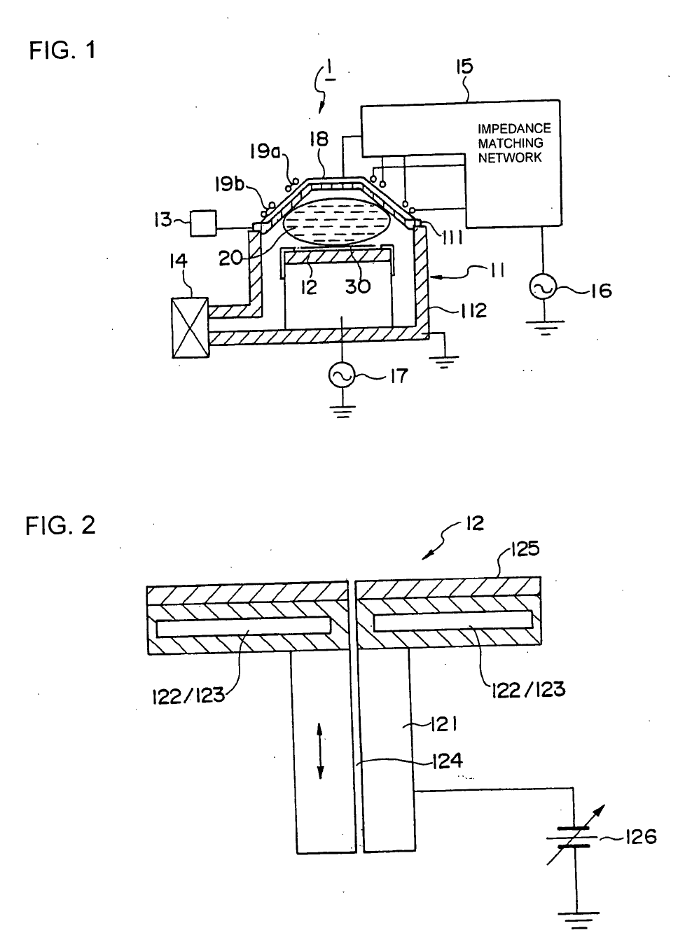

The cross-sectional view of FIG. 1 is referred to in explaining the structure of the plasma etching apparatus to which is applied the plasma processing method according to the present invention. The plasma etching apparatus 1 comprises a vacuum container 11, an electrode 12, a gas supply device 13, an exhaust system 14, an impedance matching network 15, a first high frequency power supply 16, a second high frequency power supply 17, a Faraday shield 18, and inductive coupling antennas 19a and 19b.

The vacuum container 11 is composed of a discharge unit 111 formed of an insulating material (for example, a nonconductive material such as quartz or ceramic) having disposed therein a plasma generating unit, and a processing unit 112 having an electrode 12 for mounting a substrate 30 to be subjected to processing. The processing unit 112 is earthed, and the electrode 12 is fixed to the processing unit 112 via an insulating material. Inductive coupling antennas 19a and 19b connected via an impedance matching network 15 to the first high frequency power supply 16 are attached via a Faraday shield 18 to the discharge unit 111 so as to form a plasma 20.

In the present embodiment, an etching apparatus 1 having coil-like inductive coupling antennas 19a and 19b disposed at the periphery of the discharge unit 111 is used to illustrate a typical example. Process gas is fed to the vacuum container 11 from a gas supply device 13, and at the same time, the interior of the vacuum container is evacuated by the exhaust system 14 to a predetermined pressure. The process gas fed from the gas supply device 13 to the vacuum container 11 turns into plasma 20 by the effect of the electric field created by the inductive coupling antennas 19a and 19b.

In order to attract ions existing in the plasma 20 to the substrate 30, the electrode 12 is connected to a second high frequency power supply 17 to apply bias voltage thereto. The substrate 30 is etched by plasma 20.

Now, the drawing of FIG. 2 is referred to in explaining the structure of the electrode 12. The electrode 12 is supported by a support axis 121 that can be moved in the vertical (up-down) direction, and the temperature of the electrode 12 is controlled via a circulated coolant 122 or a ceramic heater 123, while the thermal conduction between the electrode 12 and substrate 30 is realized by a coolant gas introduced through a coolant gas pipe 124, to thereby control the temperature of the substrate. A ceramic insulator 125 is mounted on the surface of the electrode 12. Further, voltage is applied to the electrode 12 from a DC power supply 126 for electrostatic chuck, so as to chuck (hold) the substrate onto the electrode 12.

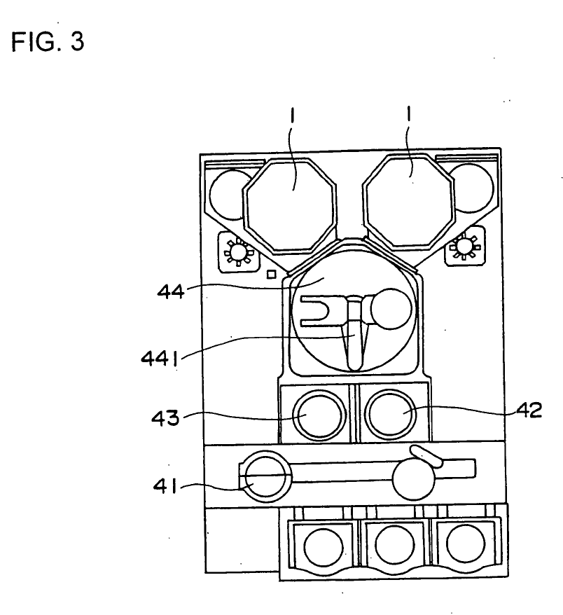

Now with reference to FIG. 3, the outline of the structure of the plasma processing apparatus using the plasma etching apparatus 1 shown in FIG. 1 will be explained. The plasma processing apparatus comprises an atmospheric loader 41, an unload lock chamber 42, a load lock chamber 43, a vacuum transfer chamber 44, and plural plasma etching apparatuses 1, 1.

The atmospheric loader 41 is communicated with the unload lock chamber 42 and the load lock chamber 43. The unload lock chamber 42 and the load lock chamber 43 are connected with the vacuum transfer chamber 44. The vacuum transfer chamber 44 is connected with two plasma etching apparatuses 1, 1. The substrate is conveyed via the atmospheric loader 41 into the load lock chamber 41, and from the load lock chamber 41 it is carried by a vacuum transfer robot 441 disposed inside the vacuum transfer chamber 44 via the vacuum chamber 44 into the plasma etching apparatus 1 to be subjected to etching. The etched substrate is taken out of the plasma etching apparatus 1 by the vacuum transfer robot 441 and transferred via the vacuum transfer chamber 44 to the unload lock chamber 42. Thereafter, the substrate is taken out of the unload lock chamber 42 by the atmospheric loader 41.

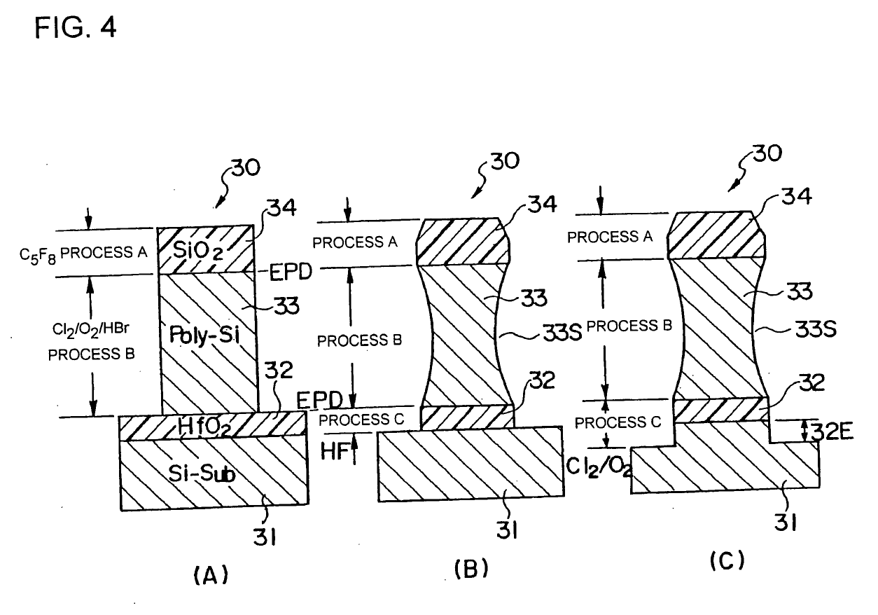

The above-mentioned plasma processing apparatus is used to etch the substrate 30 illustrated in FIG. 4(A). According to substrate 30, a high-dielectric-constant gate insulating film (HfO₂ film) 32 is formed on a Si (silicon) substrate layer 31. Thereafter, a Poly-Si layer 33 is formed on the HfO₂ film 32. Next, an SiO₂ mask 34 is formed on the Poly-Si layer 33 to create a line mask pattern (process A), by which the Poly-Si layer 33 is etched so that a line pattern is created by the SiO₂ mask 34 and Poly-Si layer 33.

Ar+CH₄ gas is used as etching gas for etching the high-dielectric-constant gate insulating film 32.

The etching conditions for etching the HfO₂ film 32 are as follows; Ar+CH₄ (0-10%) : 50-1000 ml/min, processing pressure: 0.5-3 Pa, source high frequency power: 600-1500 W, bias high frequency power: 30-300 W, and electrode temperature: 25-550° C. These etching conditions can be changed by adjusting the setting of the etching apparatus.

Table 1 shows the HfO₂ etching conditions according to the present invention. In the HfO₂ etching conditions, the etching gas is Ar+4% CH₄ mixed gas, the flow rate of which is 200 ml/min, the pressure is 1 Pa, the output of S-RF is 600 W, the output of B-RF is 200 W, the FSV is 100 V, the VC4 is 40%, the electrode temperature is 400° C., the EL is 96 mm, and the process time is 150 seconds.

TABLE 1

| Ar + CH₄ | | | | | | Electrode | | | |
|---|---|---|---|---|---|---|---|---|---|
| (4%) | Press | S-RF | B-RF | FSV | VC4 | Temp. | EL | Time | |
| ml/min | Pa | W | W | V | % | ° C. | mm | s | Note |
| 200 | 1 | 600 | 200 | 100 | 40 | 400 | 96 | 150 | Time |
| | | | | | | | | | fixed |

With reference to Table 2, we will explain the result of comparison of the etching rate of Poly-Si, SiO₂ and HfO₂, and the selective ratio of HfO₂/Poly-Si, between the embodiment of the present invention applying the plasma etching method according to the HfO₂ etching conditions listed in Table 1 and a prior art example based on conventional conditions (Cl₂/Hbr/O₂ gas etc.).

TABLE 2

| | | Prior art |
|---|---|---|
| | Embodiment: | conditions: |
| | Ar + CH₄/400° C. | (Cl₂/HBr/O₂ gas etc) |
| Poly-Si E/R | 4.3 nm/min | >100 nm/min |
| SiO₂ E/R | 5.3 nm/min | 1.0 nm/min |
| HfO₂ E/R | 1.8 nm/min | 1.0 nm/min |
| HfO₂/Poly-Si | 0.4 | <0.01 |
| Selective ratio | | |

When utilizing the Ar gas+CH₄ (4%) gas according to the conditions of the present embodiment, the etching rate of Poly-Si was 4.3 nm/min, the etching rate of SiO₂ was 5.3 nm/min, and the etching rate of HfO₂ was 1.8 nm/min. Accordingly, the selective ratio of HfO₂/Poly-Si was 0.4. On the other hand, when utilizing the conventional Cl₂/HBr/O₂ gas, the etching rate of Poly-Si was 100 nm/min or higher, the etching rate of SiO₂ was 1.0 nm/min, and the etching rate of HfO₂ was 1.0 nm/min. Accordingly, the selective ratio of HfO₂/Poly-Si was 0.01 or smaller.

In other words, by etching the high-dielectric-constant gate insulating film (HfO₂) 32 by the conditions shown in Table 1, it is possible to achieve a high Poly-Si (Si)/HfO₂ etching selective ratio (HfO₂: 1.8 nm/min, Poly-Si: 4.3 nm/min, HfO₂/Poly-Si selective ratio: 0.4).

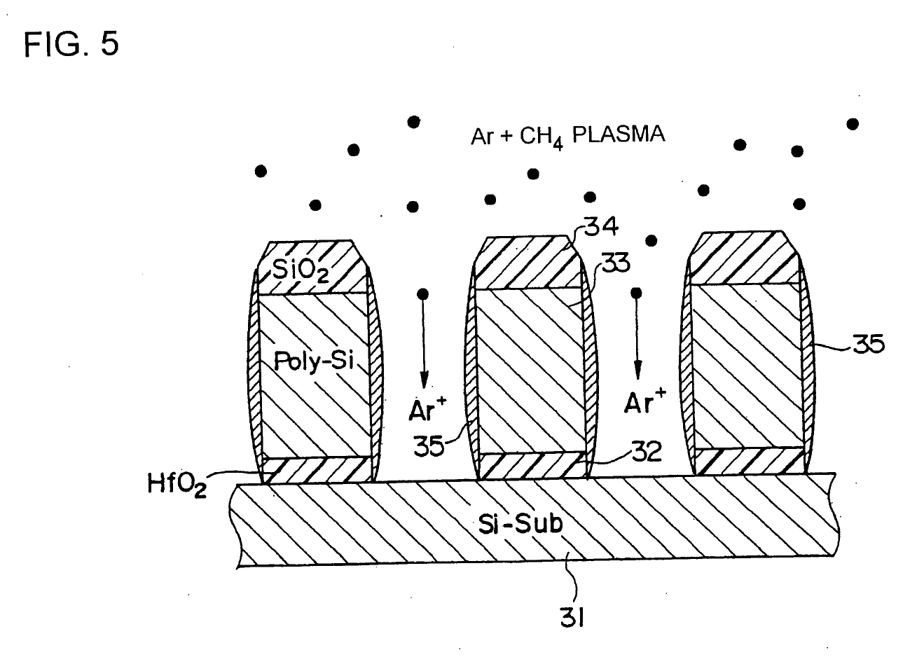

As shown in FIG. 5, Ar is used to perform sputter etching of the HfO₂ film with a high etching rate, so that the etching rate of the Si substrate layer 31 becomes small with respect to the HfO₂ film 32, and the etching of the HfO₂ film 32 can be completed while only a small portion of the Si substrate layer 31 is damaged, minimizing the loss of the Si substrate layer 31.

Further, by adding a CH-radical-containing gas (CH₄) to the Ar gas for etching the HfO₂ film 32, reaction byproducts and CH radicals are deposited on the side walls of the SiO₂ film mask 34 and the Poly-Si layer 33 thereby forming a side wall protection layer 35, suppressing the occurrence of side etching. Furthermore, the adhesion of reaction byproducts on the Si substrate layer 31 by CH radicals realizes advantageous selective ratio of the Si substrate layer 31.

According thereto, it is possible to suppress the occurrence of side etching of the Poly-Si layer 33 and the amount of loss of the Si substrate layer 31.

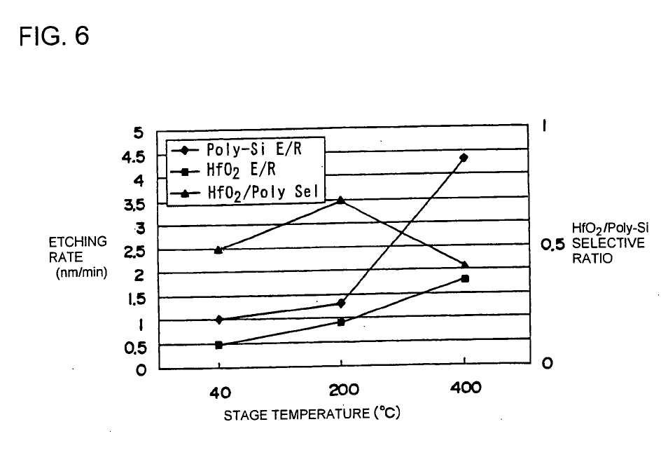

With reference to FIG. 6 and Table 3, the relationship between the temperature of substrate 30 (temperature of electrode 12), the etching rate of Poly-Si and HfO₂, and the selective ratio of HfO₂/Poly-Si are explained.

TABLE 3

| | Stage temperature (° C.) | | |
|---|---|---|---|
| | 40 | 200 | 400 |
| Poly-Si E/R | 1.0 | 1.3 | 4.3 |
| HfO₂ E/R | 0.5 | 0.9 | 1.8 |
| HfO₂/Poly Selective ratio | 0.5 | 0.7 | 0.4 |

When the substrate temperature was 40° C., the Poly-Si etching rate was 1.0 nm/min, the HfO₂ etching rate was 0.5 nm/min, and the HfO₂/Poly-Si selective ratio was 0.5. When the substrate temperature was 200° C., the Poly-Si etching rate was 1.3 nm/min, the HfO₂ etching rate was 0.9 nm/min, and the HfO₂/Poly-Si selective ratio was 0.7. When the substrate temperature was 400° C., the Poly-Si etching rate was 4.3 nm/min, the HfO₂ etching rate was 1.8 nm/min, and the HfO₂/Poly-Si selective ratio was 0.4. As above, if the electrode temperature is higher than 40° C., a preferable HfO₂/Poly-Si selective ratio can be achieved, but the upper limit of the temperature depends on the maximum endurable temperature of the electrode. For example, if an AlN electrode is utilized, the electrode can be heated up to a maximum temperature of 550° C.

Further, CHF₃ and CH₂F₂ are also examples of gases having side wall protecting effects, but since these gases contain F that cause F ions and F radicals to be generated within the plasma, it becomes impossible to achieve a high selective ratio between the HfO₂ film and the SiO₂ film or the Poly-Si film, so these gases are not suitable for processing the high-dielectric-constant gate insulating film from the point of view of shape controllability.

According to the conventional high-dielectric-constant gate insulating film etching such as gas etching using Cl₂/O₂/HBr or wet etching using HF, the Poly-Si/HfO₂ etching selective ratio or the Si/HfO₂ etching selective ratio is 0.1 or smaller, so in order to suppress the occurrence of side etching of the Poly-Si layer, it is necessary to increase the wafer bias high frequency power and to lower the temperature of the electrode, or to add a gas having side wall protection effects. However, if the wafer bias high frequency power is increased, it becomes impossible to obtain a high selective ratio with the upper resist or the SiO₂ mask 34, so that patterns can no longer be formed, and the amount of Si loss (32E) after HfO₂ etching is increased. Furthermore, HfO₂ and other high-dielectric-constant gate insulating film materials have very high boiling points and have stable characteristics, so there are concerns that etching may not progress if the electrode temperature is reduced extremely.

The above example utilizes HfO₂ as the material for forming the high-dielectric-constant gate insulating film, but other than HfO₂, materials such as HfSiO₂, HfSiON, HfSiN, HfAlₓO_{y}, ZrO₂, La₂O₃ and (Al,Hf)Oₓ can also be used to form the high-dielectric-constant gate insulating film.

Further, the above example utilizes Ar gas as an example of the inert gas, but He gas can also be used as inert gas to achieve the same effects. Moreover, Xe gas and Kr gas can also be used as inert gas.

Moreover, the illustrated example utilizes CH₄ gas as the gas containing CH radicals added to the inert gas, but CH₂—CH₂ gas can also be used to achieve the same effects.

Various plasma etching gases can be used according to the present invention, but Ar gas, He gas, Ar+CH₄ mixed gas, He+CH₄ mixed gas and Ar+He+CH₄ mixed gas are especially preferable. By using these mixed gases, in addition to the HfO₂ film sputter etching effect and the sidewall protection effect by the reaction byproducts achieved by using the inert gas (Ar, He), the CH radicals cause adhesion of reaction byproducts to the Poly-Si film, Si substrate and SiO₂ film, by which a preferable selective ratio between the Poly-Si film, Si substrate and SiO₂ film is achieved.

According to the present invention, gas plasma etching of a high-dielectric-constant gate insulating film such as HfO₂ is conducted using Ar gas, He gas, Ar+CH₄ mixed gas, He+CH₄ mixed gas or Ar+He+CH₄ mixed gas, making it possible to realize a high etching selective ratio against the Poly-Si film, the Si film and the SiO₂ film. The present invention advantageously reduces the side etching of the side walls of the Poly-Si gate portion or the loss of the Si substrate during etching of the high-dielectric-constant gate insulating film such as HfO₂.

What is claimed is:

1. A plasma etching apparatus comprising:
a means for introducing either an inert gas or a mixed gas including an inert gas and a gas containing CH radicals into a vacuum container;
an electrode for supporting a substrate by electrostatic chuck;
a plasma processing means for processing with a plasma of said gas a high-dielectric-constant gate insulating film formed of a material selected from the group consisting of HfO₂, HfSiO₂, HfSiₓN_{y}, HfSiON, HfAlₓO_{y}, ZrO₂, La₂O₃, (Al, Hf)Oₓ and Y₂O₃ disposed on said substrate electrostatically chucked to said electrode; and
a means for controlling the time for carrying out the plasma processing.

2. The plasma etching apparatus according to claim 1, wherein said inert gas is selected from the group consisting of Ar gas, He gas and a mixture of Ar gas and He gas, and said gas containing CH radicals is CH₄.

3. The plasma etching apparatus according to claim 2, wherein said insulating film is a laminated film formed on a substrate and comprising two or more layers including at least one layer of high-dielectric-constant gate insulating film, and said laminated film is subjected to etching.

4. A plasma processing apparatus comprising:
an atmospheric loader;
a vacuum transfer chamber having a vacuum transfer robot disposed therein;
two lock chambers connecting said atmospheric loader and said vacuum transfer chamber; and
plural plasma etching apparatuses connected to said vacuum transfer chamber, each said plasma etching apparatus comprising a means for introducing either an inert gas or a mixed gas including an inert gas and a gas containing CH radicals into a vacuum container, an electrode for supporting a substrate by an electrostatic chuck, a plasma processing means for processing with a plasma of said gas a high-dielectric-constant gate insulating film formed of a material selected from the group consisting of HfO₂, HfSiO₂, HfSiₓN_{y}, HfSiON, HfAlₓO_{y}, ZrO₂, La₂O₃, (Al, Hf)Oₓ and Y₂O₃ disposed on said substrate electrostatically chucked to said electrode, and a means for controlling the time for carrying out the plasma processing.
